(19) United States
(12) Patent Application Publication
(10) Pub. No.: US 2010/0230815 A1
(43) Pub. Date: Sep. 16, 2010

(54) SEMICONDUCTOR DEVICE

(75) Inventors: Jung-Chih Tsao, Taipei City (TW); Kei-Wei Chen, Taipei (TW); Yu-Ku Lin, Hsinchu City (TW)

Correspondence Address: THOMAS, KAYDEN, HORSTEMEYER & RISLEY LLP, 600 GALLERIA PARKWAY, 15TH FLOOR, ATLANTA, GA, 30339, US

(73) Assignee: TAIWAN SEMICONDUCTOR MANUFACTURING CO., LTD., Hsin-Chu (TW)

(21) Appl. No.: 12/785,618

(22) Filed: May 24, 2010

Related U.S. Application Data
(62) Division of application No. 11/294,789, filed on Dec. 6, 2005.

(51) Int. Cl. H01L 23/522; H01L 23/48

(52) U.S. Cl. 257/751; 257/758; 257/E23.011; 257/E23.145

(57) ABSTRACT

Semiconductor devices and methods for fabricating the same. An exemplary device includes a substrate, a dielectric layer, a protection layer, and a conformal barrier layer. The dielectric layer overlies the substrate and comprises an opening. The opening comprises a lower portion and a wider upper portion, exposing parts of the substrate. The bottoms of the upper portion act as shoulders of the opening. The protection layer overlies at least one shoulder of the opening. The conformal barrier layer is disposed in the opening and overlies the protection layer and the dielectric layer, wherein etching resistance of the protection layer against inert-gas plasma is higher than that of the barrier layer.

### CROSS REFERENCE TO RELATED APPLICATIONS

This application is a Divisional of pending U.S. patent application Ser. No. 11/294,789, filed on Dec. 6, 2005, the entirety of which is/are incorporated by reference herein.

### BACKGROUND

The invention relates to semiconductor technology, and more specifically to dual damascene application.

Interconnect structures in IC (Integrated Circuit) typically include semiconductor structures, such as transistors, capacitors, resistors, and the like, formed on a substrate. One or more conductive layers formed of a metal or metal alloy separated by dielectric layers are formed over the semiconductor structures to interconnect the semiconductor structures and to provide external contacts to the semiconductor structures. Copper is currently utilized for the metal lines in interconnect structures due to the high conductivity thereof. Dual damascene structures also have been developed as they require fewer processing steps.

Dual damascene processing involves simultaneous formation of a metal line and a plug respectively in a trench and a via formed in a dielectric layer. The bottom of the via is typically a contact structure for an underlying metal line or semiconductor structure.

A barrier layer is deposited along sidewalls and bottom of the via and the trench to prevent diffusion of compositions of the metal line and the plug therein into the neighboring dielectric layer. The barrier layer, however, is typically not as ideal a conductor as the metal line, thus, the resistance of the resulting interconnect structure is undesirably increased.

### SUMMARY

Thus, embodiments of the invention provide semiconductor devices and methods for fabricating the same, preventing high resistance and improving device reliability and electrical performance.

Embodiments of the invention provide a semiconductor device comprising a substrate, a dielectric layer, a protection layer, and a conformal barrier layer. The dielectric layer overlies the substrate and comprises an opening. The opening comprises a lower portion and a wider upper portion, exposing parts of the substrate. The bottoms of the upper portion act as shoulders of the opening. The protection layer overlies at least one shoulder of the opening. The conformal barrier layer is disposed in the opening and overlies the protection layer and the dielectric layer, wherein etching resistance of the protection layer against inert-gas plasma is higher than that of the barrier layer.

Embodiments of the invention further provide a semiconductor device comprising a substrate, a dielectric layer, a protection layer, and a conformal barrier layer. The dielectric layer overlies the substrate and comprises an opening. The opening comprises a lower portion and a wider upper portion, exposing parts of the substrate. The bottoms of the upper portion act as shoulders of the opening. The protection layer overlies sidewalls and shoulders of the opening. The conformal barrier layer overlies the protection layer, wherein etching resistance of the protection layer against inert-gas plasma is higher than that of the barrier layer.

Embodiments of the invention further provide a semiconductor device comprising a substrate, a first dielectric layer, a dielectric protection layer, a first interface, a second dielectric layer, a second interface, an opening, and a conformal barrier layer. The first dielectric layer overlies the substrate. The dielectric protection layer overlies the first dielectric layer, thus, a first interface is formed between the first dielectric layer and the protection layer. The second dielectric layer overlies the protection layer, thus, a second interface is formed between the protection layer and the second dielectric layer. The opening comprises a lower portion and a wider upper portion. The lower portion extends through the first dielectric layer and exposes parts of the substrate. The wider upper portion extends through the second dielectric layer and connects the lower portion at a position between the first interface and the second interface, exposing parts of the protection layer. The conformal barrier layer is disposed in the opening and overlies the protection layer and sidewalls of the opening, wherein etching resistance of the protection layer against inert-gas plasma is higher than that of the barrier layer.

Embodiments of the invention further provide a semiconductor device comprising a substrate, a first dielectric layer, a first interface, a composite dielectric barrier layer, a second interface, a second dielectric layer, and an opening. The first dielectric layer overlies the substrate. The composite dielectric barrier layer overlies the first dielectric layer, thus, a first interface is formed between the first dielectric layer and the protection layer. The second dielectric layer overlies the protection layer, thus, a second interface is formed between the protection layer and the second dielectric layer. The opening comprises a lower portion and a wider upper portion. The lower portion extends through the first dielectric layer and exposes parts of the substrate. The wider upper portion extends through the second dielectric layer and connects the lower portion at a position between the first interface and the second interface, exposing parts of the protection layer.

Embodiments of the invention further provide a method for fabricating a semiconductor device. First, a substrate is provided. The substrate comprises an overlying dielectric layer. The substrate comprises an opening. The opening, comprising a lower portion and a wider upper portion, exposes parts of the substrate. The bottoms of the upper portion act as shoulders of the opening. A protection layer is then formed overlying sidewalls and shoulders of the opening, and the exposed substrate. Next, a first sub-layer of a barrier layer is conformally formed overlying the protection layer, wherein etching resistance of the protection layer against inert-gas plasma is higher than that of the barrier layer. Further, a sputtering etching procedure utilizing inert-gas plasma is performed to remove the protection layer and the barrier layer at the bottom of the lower portion of the opening, exposing parts of the substrate. Finally, a second sub-layer of the barrier layer is conformally formed overlying the first sub-layer of the barrier layer.

Embodiments of the invention further provide a method for fabricating a semiconductor device. First, a substrate is provided. A first dielectric layer is then formed overlying the substrate. Next, a dielectric protection layer is formed overlying the first dielectric layer. Next, a second dielectric layer is formed overlying the protection layer. Next, the first dielectric layer, the dielectric protection layer, and the dielectric protection layer, are patterned, forming an opening comprising a lower portion and a wider upper portion. The lower portion extends through the first dielectric layer and exposes parts of the substrate. The wider upper portion extends through the second dielectric layer and connects the lower portion, exposing parts of the protection layer. Next, a first sub-layer of a barrier layer is conformally formed overlying the protection layer, sidewalls of the opening, and the bottom of the lower portion of the opening. The etching resistance of the protection layer against inert-gas plasma is higher than that of the barrier layer. Further, a sputtering etching procedure utilizing inert-gas plasma is performed to remove the protection layer and the barrier layer at the bottom of the lower portion of the opening, exposing parts of the substrate. Finally, a second sub-layer of the barrier layer is conformally formed overlying the first sub-layer of the barrier layer.

Further scope of the applicability of the invention will become apparent from the detailed description given hereinafter. It should be understood, however, that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The invention can be more fully understood by reading the subsequent detailed description in conjunction with the examples and references made to the accompanying drawings, which are given by way of illustration only, and thus are not limitative of the invention, and wherein:

FIGS. 1A and 1B are cross-sections of wiring layers of a semiconductor device, illustrating the occurrence of micro-trenches.

FIGS. 2A and 2B are cross-sections of semiconductor devices of a first embodiment of the invention.

FIG. 3 is a cross-section of semiconductor devices of a second embodiment of the invention.

FIGS. 4A and 4B are cross-sections of fabrication methods of semiconductor devices of the invention.

FIG. 5 is a cross-section of a semiconductor device of a third embodiment of the invention.

FIGS. 6A through 6E are cross-sections of fabrication methods of a semiconductor device of the invention.

### DESCRIPTION

The following embodiments are intended to illustrate the invention more fully without limiting the scope of the claims, since numerous modifications and variations will be apparent to those skilled in this art.

In co-pending application Ser. No. 10/995,752 and 11/100,912, the barrier layer at the bottom of the via is thinned, or alternatively, removed, followed by formation of an inlaid metal interconnect. The underlying contact structure is potentially recessed, and the inlaid metal interconnect extends into the underlying contact structure to reduce resistance therebetween when the barrier layer at the bottom of the via is removed.

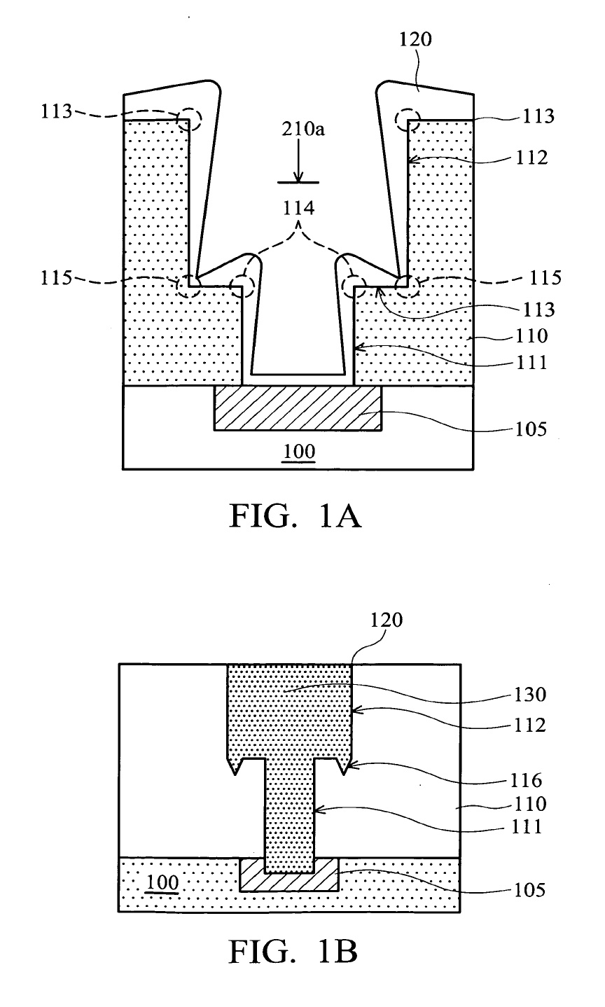

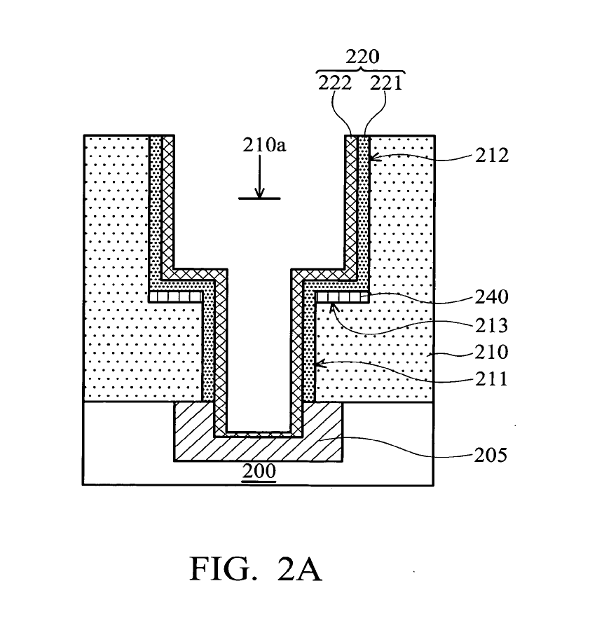

The inventors, however, discover the devices disclosed by the co-pending applications have potential risks for device reliability and electrical performance. The inventors then found a root cause as shown in FIGS. 1A and 1B.

In FIG. 1A, a substrate 100 with a contact region 105 comprises a dielectric layer 110 thereon. The dielectric layer 110 comprises a dual damascene opening 110a exposing the contact region 105. The opening 110a comprises a lower portion 111 and a wider upper portion 112 connecting thereto. The bottoms of the upper portion act as shoulders 113 of the opening 110a. A conformal barrier layer 120 is deposited on the exposed contact area 105 and dielectric layer 110 in the opening 110a. The barrier layer 120, near corners 113 and 114, is potentially thicker and that near shoulder edges 115 is potentially thinner than a predetermined thickness. Next, the bottom barrier layer 120 is thinned, or alternatively, removed by a method such as sputtering etching utilizing bombardment of inert gas, i.e. argon, plasma. The sputtering etch is not selective, and the shoulder barrier layer 120 is also etched. As described, the barrier layer 120 near shoulder edges 115 is potentially thinner, resulting in being completely consumed during sputtering etching. Thus, the underlying dielectric layer 110 is etched and recessed, forming undesired micro-trenches 116 (shown in FIG. 1B) at shoulder edges 115.

Thereafter, the deposition of the barrier layer 120 is continued, followed by deposition of an inlaid metal 130, and thus, a semiconductor device shown in FIG. 1B is completed, affecting the device performance and reliability. The continued deposition of the barrier layer 120 is potentially incomplete, resulting in provision of a diffusion path into the dielectric layer 110 for atoms in the inlaid metal 130. Further, formation of the micro-trenches 116 may substantially deviate from the dielectric constant of the dielectric layer 110 from the predetermined value, thus, the electrical performance of the semiconductor device is affected. Furthermore, formation of the micro-trenches 116 substantially expand the inlaid metal 130, and thus, the complete resistance and/or impedance thereof potentially deviate from the predetermined and/or specified values, affecting electrical performance of the device.

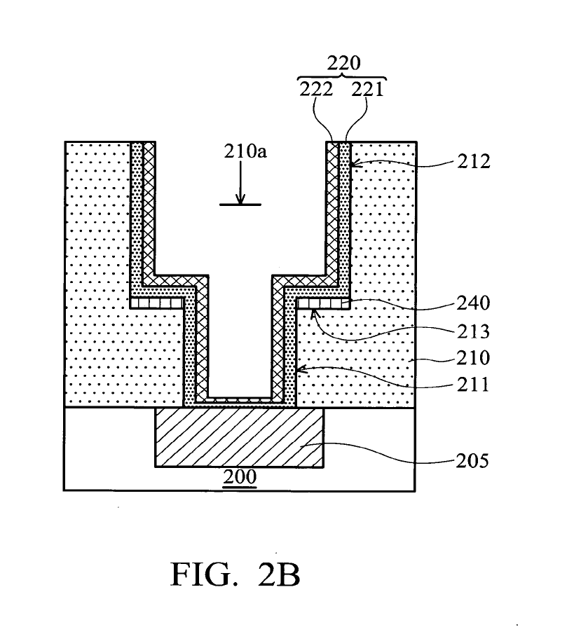

FIGS. 2A and 2B show semiconductor devices of the first embodiment of the invention.

In FIG. 2A, the semiconductor device comprises a substrate 200, a dielectric layer 210, a protection layer 240, and a conformal barrier layer 220.

The substrate 200 comprises semiconductor materials such as silicon, germanium, silicon germanium, compound semiconductor, or other known semiconductor materials. The substrate 100 typically comprises processed active devices, such as diodes, transistors, other known active devices, resistors, capacitors, inductors, and/or other known passive devices (not shown) therein.

In some cases, the substrate 200 may comprise an exposed contact region 205 for the described devices or of parts of an interconnect layer of the semiconductor device. The contact region 205 is preferably recessed when the contact region is part of an interconnect layer of the semiconductor device, thus, the contact resistance between the contact region 205 and a subsequently formed inlaid metal (not shown) acting as an upper interconnect layer is reduced. In one embodiment, the contact region 205 comprises copper.

The dielectric layer 210 overlies the substrate 200. In some cases, the dielectric layer 210 is oxide-based, such as BPSG layer, an FSG layer, a layer formed by CVD utilizing precursors comprising TEOS, or other known oxide-based layers. In some cases, dielectric constant of the dielectric layer 210 is less than 4 (low-k), and preferably as large as 3 or less, and the dielectric layer 210 may comprise any known low-k material. In some cases the dielectric layer 210 is composite and comprises etch stop sub-layers and main sub-layers as subsequently exemplified. Further, the dielectric layer 210 preferably comprises an underlying etch stop sub-layer for processing the formation of the opening 210a and preventing diffusion when the contact region 205 comprises copper, for example.

The dielectric layer 210 comprises an opening 210a. In this embodiment, the opening 210a is a dual-damascene opening and comprises a lower portion 211 and an upper portion 212 wider than the lower portion 211. The lower portion 211 exposes the substrate 200. Specifically, the lower portion 211 exposes the contact region 205 when the substrate 200 comprises the contact region 205. The bottoms of the upper portion 212 act as shoulders 213 of the opening 210a. As described, the contact region 205 is recessed and the opening 210a extends into the contact region 205.

The protection layer 240 overlies at least one shoulder 213 of the opening 210a, and preferably overlies all shoulders 213. The conformal barrier layer 220 is disposed in the opening 210a and overlies the protection layer 240 and the dielectric layer 240 to prevent atoms of the subsequently formed inlaid metal from diffusing into the dielectric layer 210.

In some cases, the barrier layer 220 is a composite layer for improving the anti-diffusion performance thereof. In this embodiment, the barrier layer 220 comprises a first sub-layer 221 and a second sub-layer 222. The first sub-layer 221 is deposited in the opening 210a, followed by etched to remove the first sub-layer 221 at the bottom of the lower portion 211 of the opening 210a for reducing, potentially recessing the contact region 205. The etch to the first sub-layer 221 is preferably performed by sputtering etching utilizing inert-gas plasma such as argon or other inert gases. The second sub-layer 222 is then conformally deposited overlying the first sub-layer 221 and the recessed portion. The second sub-layer 222 at the bottom of the opening 210a is preferably thinned or removed by sputtering etching utilizing inert-gas plasma such as argon or other inert gases to reduce the resistance between the contact region 205 and the subsequently formed inlaid metal. In this embodiment, the second sub-layer 222 is thinned.

The first sub-layer 221 preferably comprises TaN and the second sub-layer 222 preferably comprises Ta when the subsequently formed inlaid metal is copper. As measured by the inventors, for example, when utilizing argon plasma during the described etching, the etching rate to a low-k dielectric layer is as twice as a Ta/TaN layer or greater, and to an FSG dielectric layer is as 1.3 times as a Ta/TaN layer or larger. The etching resistance of the protection layer 240 against inert-gas plasma is higher than that of the barrier layer 220. Even when the barrier layer 220 overlying the shoulders 213 of the opening 210a is consumed during the described thinning or removing procedures, the exposed protection layer 240 can efficiently resist the etching of the inert-gas plasma, preventing etch of the underlying dielectric layer 210 and formation of the described micro-trenches. Specifically, the etching rate of the protection layer 240 by sputtering etching is less than the etching rate of the second layer 220. When the barrier layer 220 is the described Ta/TaN layer, for example, the protection layer 240 is preferably nitride-based. In some cases, the protection layer 240 comprises nitrides such as TaN, TiN, SiN, TaSiN, or other nitride-based materials, but rather than TaN when the barrier layer 220 comprises TaN. In some cases, the protection layer 240 comprises composite sub-layers as substantially described. In some cases, the protection layer 240 is between 10 and 100 Å thick. In some cases, the protection layer 240 is an atomic level layer.

In FIG. 2B, alternatively, the first sub-layer 221 and the second sub-layer 222 of the barrier layer 220 at the bottom of the opening 210 is thinned, and the contact region 205 is not recessed. In this case, the described resistance issue is minor, or alternatively, the contact region 205 cannot be recessed.

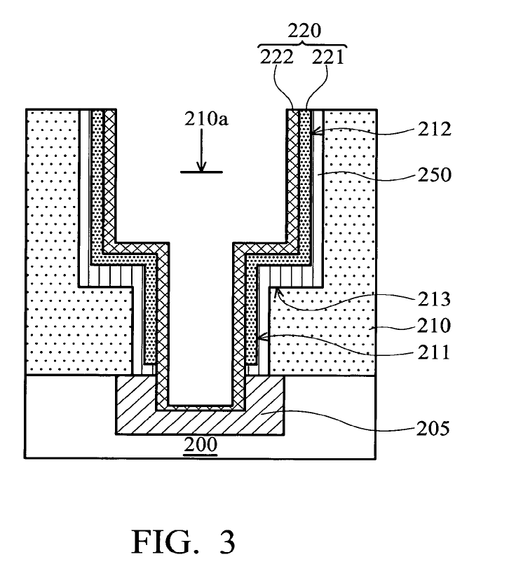

FIG. 3 shows semiconductor devices of the second embodiment of the invention. The semiconductor device comprises a protection layer 250 instead of the layer 240 as compared to that shown in FIG. 2A. The protection layer 250 conformally overlies the sidewalls and the shoulders. In some cases, the protection layer 250 are nitride-based, such as TaN, TiN, SiN, TaSiN or other nitride-based materials, but rather than TaN when the barrier layer 220 comprises TaN. Details regarding properties of the protection layer 250 are the same as the protection layer 240, and thus, are omitted herefrom.

In FIG. 3, the contact region 205 is recessed. In some cases, however, the contact region 205 is not recessed and thinner barrier layer 220 extends to the bottom of the lower portion 211 of the opening 210a as shown in FIG. 2B.

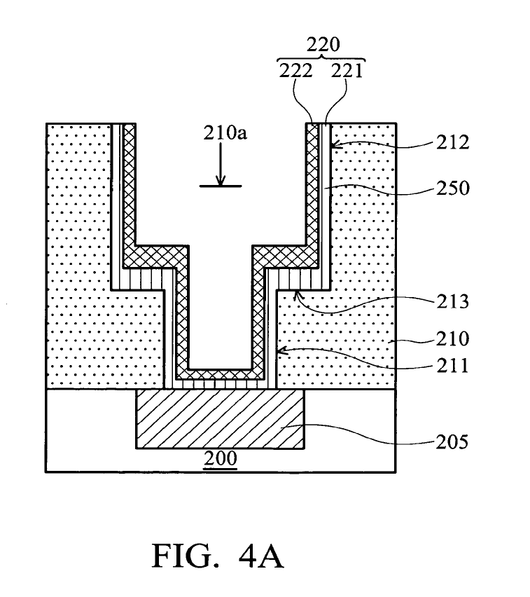

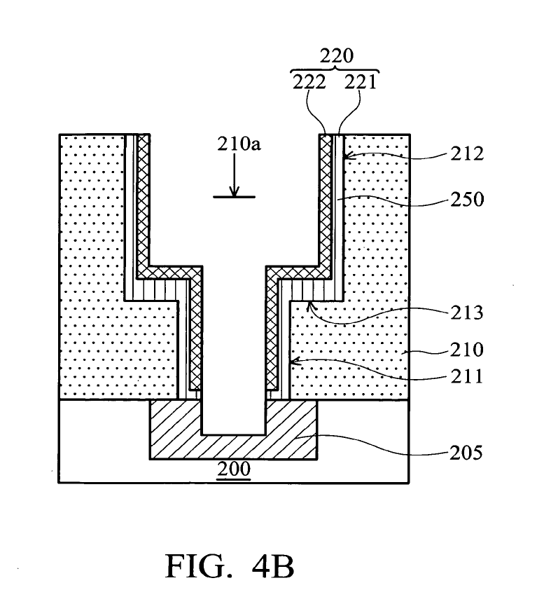

FIGS. 4A and 4B show a fabrication method for the semiconductor devices of the second embodiment of the invention.

In FIG. 4A, first, a substrate 200 is provided. In some cases, the substrate 200 may comprise an exposed contact region 205 as described. The substrate 200 comprises an overlying dielectric layer 210. The substrate 200 comprises an opening 210a. The opening 210a, comprising a lower portion 211 and a wider upper portion 212, exposes parts of the substrate 200. In some cases, the lower portion 211 exposes the contact region 205 as described. The opening 210a can be formed by any known methods for damascene structures. The bottoms of the upper portion 212 act as shoulders 213 of the opening 210a. Details regarding the substrate 200, the contact region 205, and the dielectric layer 210 are the same as those shown in FIG. 2A, and thus, are omitted herefrom.

A protection layer 250 is formed overlying sidewalls and shoulders 213 of the opening 210a, and the exposed substrate 200 (contact region 205). The protection layer 250 is preferably deposited along the profile of the opening 210a by a method such as PVD, CVD, ALCVD, or other methods. The thickness of the protection layer 250 at the bottom of the lower portion 211 is typically half of the predetermined resulting from shadow effect or less. In some cases, the protection layer 250 comprises nitrides such as TaN, TiN, SiN, or TaSiN. When the protection layer 250 comprises metal nitrides such as TaN, TiN, or TaSiN, the protection layer 250 is preferably formed by sputtering. For example, the substrate 200 is preferably disposed in a chamber (not shown), followed by introduction of nitrogen or nitrogen-containing gas, and at least a Si, Ti, Ta target is provided and bias power is applied to each desired target respectively according to the predetermined composition of the protection layer 250. Sputtering duration is determined according to the predetermined thickness of the protection layer 250. When the protection layer 250 comprises SiN, the protection layer 250 is formed by CVD or ALCVD. For example, the substrate 200 is disposed in a chamber (not shown), followed by introduction of precursors such as SiH₄ and NH₃ under a preferred condition comprising:

SiH₄ flow: from about 100 to 200 sccm and more preferably from about 150 to 180 sccm;

NH₃ flow: from about 100 to 200 sccm and more preferably from about 150 to 180 sccm;

temperature: preferably from 300 to about 400° C. and more preferably from 350 to about 380° C.;

pressure: preferably from about 2000 to 5000 mTorr and more preferably from about 3000 to 4000 mTorr;

time: preferably from about 1 to 10 seconds and more preferably from about 2 to 5 seconds; and

power: preferably from about 600 to 1000 W and more preferably from about 700 to 800 W.

Next, the barrier layer 220 is conformally formed overlying the protection layer 250. For example, when the barrier layer 220 comprises a plurality sub-layers such as sub-layers 221 and 222 shown in FIG. 3, the first sub-layer 221 is formed overlying the protection layer 250, followed by sputtering etching utilizing inert-gas plasma such as argon or other inert gases. The first sub-layer 221 and the protection layer 250 at the bottom of the lower portion 211 of the opening 210a is completely removed and the exposed substrate 200 (contact region 205) is recessed as shown in FIG. 4B. Even the first sub-layer 221 overlying shoulders 213 of the opening 210a is consumed, the protection layer 250 resists the inert-gas plasma and protects the underlying dielectric layer 210 resulting from its higher etching resistance. Moreover, the protection layer 250 overlying the shoulders 213 is thicker as described, and thus, can successfully resist the inert-gas plasma when the protection layer 250 at the bottom of the lower portion 211 of the opening 210a is completely removed. Thus, the resulting semiconductor device is substantially free of described micro-trenches.

Further, formation of the protection layer 250 further extends allowable waiting duration from exposure of the contact region 205 to formation of the barrier layer 220 (Q time). In a conventional interconnection process, a lower-level interconnect layer is exposed at atmosphere when a via and/or trench is formed. It is necessary to control Q time from exposure of the lower-level interconnect layer to formation of a barrier to prevent oxidation of the exposed surface of the lower-level interconnect layer. It is appreciated that the protection layer 250 can further protect the contact region 205 from oxidation, and thus, the Q time can be extended.

In some alternative cases that the contact region 205 is not recessed, the first sub-layer 221/protection layer 250 is preferably thinned to be as thick as 10 Å or less, for example. When the protection layer 250 comprises SiN or other dielectric materials, however, it is necessary to remove the dielectric protection layer at the bottom of the lower portion 211 of the opening 210a to prevent open circuit of the resulting devices.

Finally, the second sub-layer 222 of the barrier layer 220 is conformally formed overlying the first sub-layer 221 and the exposed substrate 200 (contact region 205). The second sub-layer 222 at the bottom of the lower portion 211 of the opening 210a can also be thinned by sputtering etching utilizing inert-gas plasma such as argon or other inert gases. Thus, the semiconductor device shown in FIG. 3 is completed.

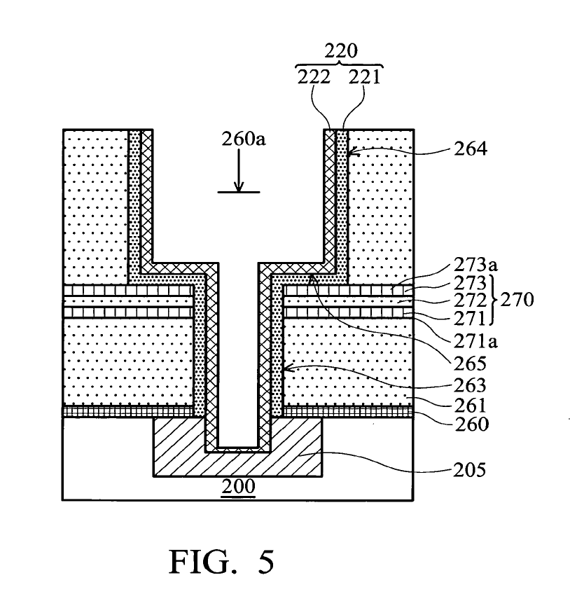

FIG. 5 shows semiconductor devices of the third embodiment of the invention. The semiconductor device comprises a composite protection layer 270 instead of the layer 240 and a composite dielectric layer instead of the dielectric layer 210 as compared to that shown in FIG. 2A.

Specifically, the semiconductor device comprising a substrate 200, a first dielectric layer 261, a dielectric protection layer 270, a second dielectric layer 262, an opening 260a, and a conformal barrier layer 220.

The first dielectric layer 261 overlies the substrate 200. The protection layer 270 overlies the first dielectric layer 261, and thus, a first interface 271a is between the first dielectric layer 261 and the protection layer 270. The second dielectric layer 262 overlies the protection layer 270, and thus, a second interface 273a is between the protection layer 270 and the second dielectric layer 262. In some cases, an optional etch stop layer 260 is disposed between the substrate 200 and the first dielectric layer 261. In one embodiment, the etch stop layer 260 comprises SiN. In some cases, the first and second dielectric layers 261, 262 are oxide-based, such as BPSG layers, FSG layers, layers formed by CVD utilizing precursors comprising TEOS, or other known oxide-based layers. In some cases, dielectric constants of the first and second dielectric layers 261, 262 are less than 4 (low-k), and preferably as large as 3 or less, and the first and second dielectric layers 261, 262 may comprise any known low-k materials.

The opening 260a comprises a lower portion 263 and a wider upper portion 264. The lower portion 263 extends through the first dielectric layer 263 and exposes parts of the substrate 200. In some cases, the contact region 205 of the substrate 200 is exposed. The wider upper portion 264 extends through the second dielectric layer 262 and connects the lower portion 263 at a position between the first interface 271a and the second interface 273a, exposing parts of the protection layer 270. Note that the description “the wider upper portion 264 connects the lower portion 263 at a position between the first interface 271a and the second interface 273a” means bottoms of the upper portion 264, shoulders 265 are substantially between the interfaces 273a and 271a.

The conformal barrier layer 220 is disposed in the opening 260a and overlies the protection layer 270 and sidewalls of the opening 260a. Details regarding the barrier layer 220 and the relationship of etching resistance between the barrier layer 220 and the protection layer 270 are the same as the barrier layer 220 and the protection layer 240 shown in FIG. 2A, and thus, are omitted herefrom.

In this embodiment, the combination of the second dielectric layer 262, the protection layer 270, the first dielectric layer 261, and the optional etch stop layer 260 acts as a composite inter-layer dielectric layer. In some cases, this combination may replace the dielectric layer 210 of one or more semiconductor devices shown in FIGS. 2A, 2B, and 3.

In some cases, the protection layer 270 is composite. In some cases, the protection layer 270 comprises a plurality of sub-layers, and composition of at least one of the sub-layers is different from at least one of others. In an exemplary embodiment, the protection layer 270 comprises three sub-layers 271 through 273 as shown in FIG. 5, and composition of the second sub-layer 272 is different from at least one of the first and third sub-layers 271, 273. Note that the quantity of sub-layers of the protection layer 270 shown in FIG. 5 is an example, and is not intended to limit the scope of the invention. Those skilled in the art will recognize the possibility of using various quantities of sub-layers to achieve the protection layer 270 shown in FIG. 5. In some cases, the sub-layer 272 is nitride-free sub-layer sandwiched by nitride-based sub-layers 271 and 273, and preferably, the dielectric constant of the sub-layer 272 is less than those of the sub-layers 271 and 273 to reduce the complete dielectric constant of the protection layer 270. In some cases, the sub-layer 272 is oxide-based, such as BPSG layers, FSG layers, layers formed by CVD utilizing precursors comprising TEOS, or other known oxide-based layers. In some cases, dielectric constants of the sub-layer 272 is less than 4 (low-k), and preferably as large as 3 or less, and the sub-layer 272 may comprise any known low-k materials. In some cases the sub-layers 271 and 273 comprise SiN. In some cases, the sub-layer 272 and either the dielectric layer 261 or 262 have substantially the same composition. In some cases, the sub-layer 272, the first dielectric layer 261, and the second dielectric layer 262 have substantially the same composition. In some cases, the protection layer 270 is between 10 and 100 Å thick.

At least one of the sub-layers 271 through 273 may be exposed on the shoulders 265, and preferably only the second sub-layer 273 is exposed on the shoulders 265 to maximize the resistant performance during inert-gas plasma etching.

In FIG. 5, the contact region 205 is recessed. In some cases, however, the contact region 205 is not recessed and the thinner barrier layer 220 extends to the bottom of the lower portion 211 of the opening 210a as shown in FIG. 2B.

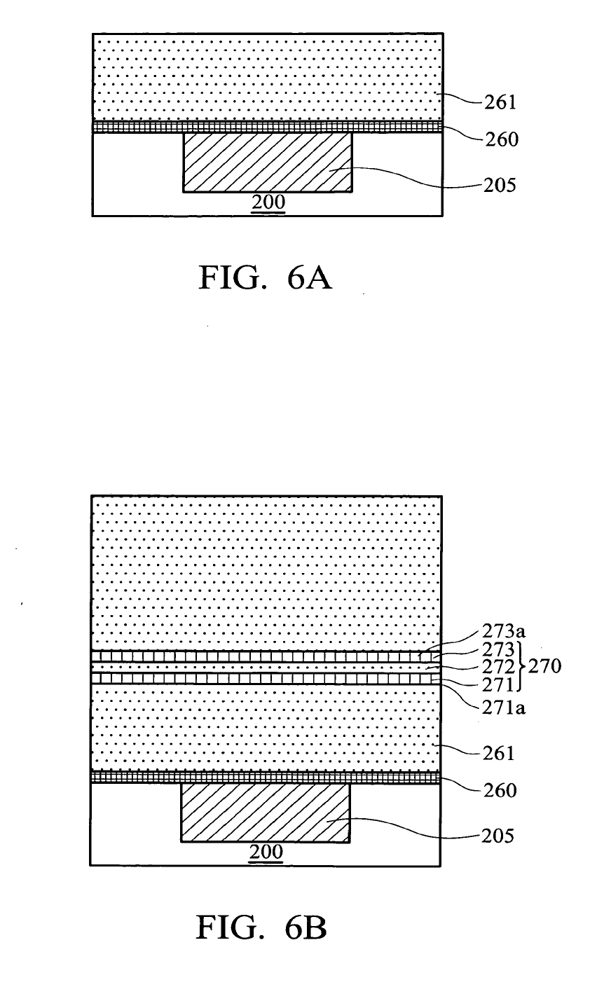

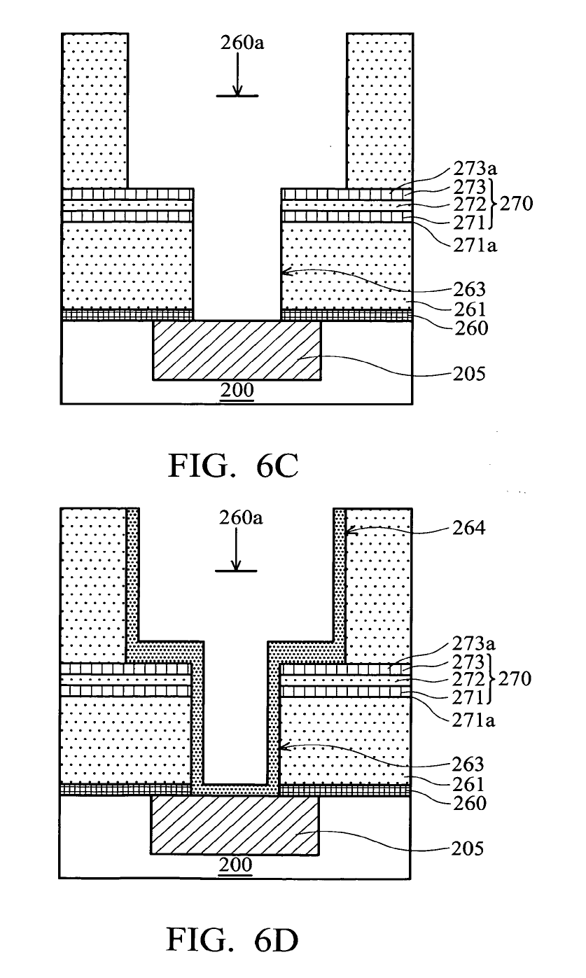

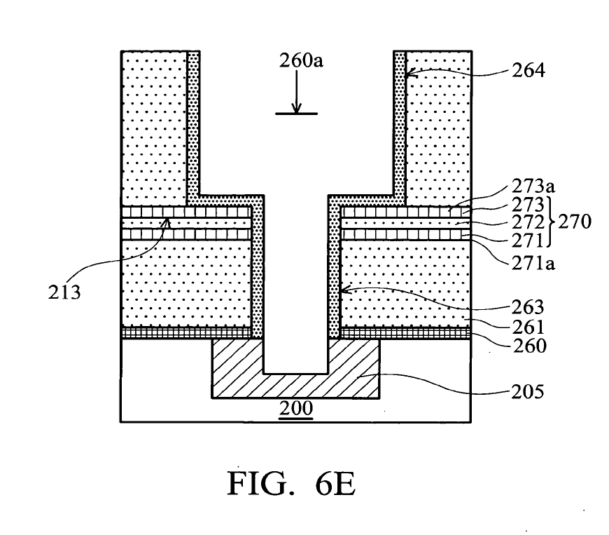

FIGS. 6A through 6D show a fabrication method for the semiconductor devices of the third embodiment of the invention.

In FIG. 6A, first, a substrate 200 is provided. In some cases, the substrate 200 may comprise an exposed contact region 205 as described. The first dielectric layer 261 is then formed overlying the substrate 200. The first dielectric layer 261 can be formed by CVD, spin-coating, or other methods. In some cases, the optional etch stop layer is formed overlying the substrate 220 prior to formation of the first dielectric layer 261.

In FIG. 6B, the described protection layer 270 is formed overlying the first dielectric layer. The protection layer 270 layer 261 can be formed by CVD, spin-coating, other methods, or a combination thereof. Next, the second dielectric 262 is formed overlying the protection layer 270. Similar with the first dielectric layer 261, the second dielectric layer 262 can be formed by CVD, spin-coating, or other methods.

In FIG. 6C, the second dielectric layer 262, the protection layer 270, the first dielectric layer 261, and the optional etch stop layer 260 is patterned to form the opening 260a. In this embodiment, the protection layer 270 can further stop the downward extension of the upper portion 264 of the opening 260a, acting as a stop layer. Consequently, at least one of the sub-layers 271 through 273 may be exposed on the shoulders 265, and preferably only the second sub-layer 273 is exposed on the shoulders 265 to maximize the resistant performance during inert-gas plasma etching.

In FIG. 6D, the barrier layer 220 is conformally formed in the opening 260a, overlying the protection layer 270 and sidewalls of the opening 260a. For example, when the barrier layer 220 comprises a plurality sub-layers such as sub-layers 221 and 222 shown in FIG. 5, the first sub-layer 221 is formed overlying the protection layer 270, sidewalls of the opening 260a, and the bottom of the lower portion 263 of the opening 260a, followed by sputtering etching utilizing inert-gas plasma such as argon or other inert gases. The first sub-layer 221 at the bottom of the lower portion 211 of the opening 210a is completely removed and the exposed substrate 200 (contact region 205) is recessed as shown in FIG. 6E. Even the first sub-layer 221 overlying shoulders 265 of the opening 260a consumes, the protection layer 270 resists the inert-gas plasma and protects the underlying dielectric layer 261 resulting from its higher etch resistance. Thus, the resulting semiconductor device is substantially free of described micro-trenches.

In some alternative cases that the contact region 205 is not recessed, the first sub-layer 221 is preferably thinned to be as thick as 10 Å or less, for example.

Finally, the second sub-layer 222 of the barrier layer 220 is conformally formed overlying the first sub-layer 221 and the exposed substrate 200 (contact region 205). The second sub-layer 222 at the bottom of the lower portion 211 of the opening 210a can also be thinned by sputtering etching utilizing inert-gas plasma such as argon or other inert gases. Thus, the semiconductor device shown in FIG. 5 is completed.

The efficacy of the inventive semiconductor devices utilizing the same at preventing formation of micro-trenches, provides improved device reliability, yield, and performance.

While the invention has been described by way of example and in terms of preferred embodiment, it is to be understood that the invention is not limited thereto. It is therefore intended that the following claims be interpreted as covering all such alteration and modifications as fall within the true spirit and scope of the invention.

What is claimed is:

1. A semiconductor device, comprising:
a substrate;
a first dielectric layer overlying the substrate;
a dielectric protection layer overlying the first dielectric layer;
a first interface between the first dielectric layer and the protection layer;
a second dielectric layer overlying the protection layer;
a second interface between the protection layer and the second dielectric layer;
an opening, comprises a lower portion and a wider upper portion, wherein the lower portion, extending through the first dielectric layer, exposes parts of the substrate, and the wider upper portion, extending through the second dielectric layer, connects the lower portion at a position between the first interface and the second interface, exposing parts of the protection layer;
a conformal barrier layer disposed in the opening, overlying the protection layer and sidewalls of the opening, wherein etching resistance of the protection layer against inert-gas plasma is higher than that of the barrier layer.

2. The device as claimed in claim 1, wherein the barrier layer further comprises a TaN sub-layer and a Ta sub-layer.

3. The device as claimed in claim 1, wherein the second barrier further overlies the substrate.

4. The device as claimed in claim 2, wherein the TaN sub-layer overlies the first barrier and the dielectric layer, but exposes parts of the substrate, and the Ta sub-layer overlies the TaN sub-layer and the substrate.

5. The device as claimed in claim 1, wherein the protection layer is nitride-based.

6. The device as claimed in claim 1, wherein the protection layer is composite.

7. The device as claimed in claim 1, wherein the protection layer comprises a nitride-free sub-layer sandwiched by at least two nitride-based sub-layers.

8. The device as claimed in claim 7, wherein dielectric constant of the nitride-free sub-layer is less than those of the nitride-based sub-layers.

9. The device as claimed in claim 1, wherein the protection layer is between 10 and 100 Å thick.

10. The device as claimed in claim 1, further comprising an etch stop layer between the substrate and the first dielectric layer.

11. A semiconductor device, comprising:
a substrate;
a first dielectric layer overlying the substrate;
a composite dielectric protection layer overlying the first dielectric layer;
a first interface between the first dielectric layer and the protection layer;
a second dielectric layer overlying the protection layer;
a second interface between the protection layer and the second dielectric layer;
an opening, comprises a lower portion and a wider upper portion, wherein the lower portion, extending through the first dielectric layer, exposes parts of the substrate, and the wider upper portion, extending through the second dielectric layer, connects the lower portion at a position between the first interface and the second interface, exposing parts of the protection layer.

12. The device as claimed in claim 11, wherein the protection layer is nitride-based.

13. The device as claimed in claim 11, wherein the protection layer comprises a nitride-free sub-layer sandwiched by at least two nitride-based sub-layers.

14. The device as claimed in claim 11, wherein dielectric constant of the nitride-free sub-layer is less than those of the nitride-based sub-layers.

15. The device as claimed in claim 11, further comprising an etch stop layer between the substrate and the first dielectric layer.
